(19) United States
(12) Patent Application Publication
(10) Pub. No.: US 2006/0134862 A1
(43) Pub. Date: Jun. 22, 2006

(54) CMOS NVM bitcell and integrated circuit

(76) Inventors: Patrice Parris, Phoenix, AZ (US); Edouard D. de Fresart, Tempe, AZ (US); Richard J. De Souza, Tempe, AZ (US); Jennifer H. Morrison, Chandler, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/015,110

(22) Filed: Dec. 17, 2004

(51) Int. Cl. H01L 21/336

(52) U.S. Cl. 438/257

(57) ABSTRACT

A non-volatile memory bitcell structure is disclosed that includes a dual capacitor structure. A first metal-insulator-metal (MIM) capacitor having a first capacitance value includes a first top plate, a first bottom plate, and a first dielectric disposed in-between the first top plate and the first bottom plate. A second metal-insulator-metal (MIM) capacitor having a second capacitance value includes a second top plate, a second bottom plate, and a second dielectric disposed in-between the second top plate and the second bottom plate. An element of the first MIM capacitor is electrically coupled in common with an element of the second MIM capacitor. In addition, the first capacitance value is greater than the second capacitance value.

### BACKGROUND

The present disclosure relates generally to integrated circuits and semiconductor devices, and more particularly, to a CMOS Non-Volatile Memory (NVM) bitcell.

In applications that use CMOS, including CMOS logic integrated circuits (ICs), some NVM capability is usually desirable. Because many of these applications are cost-sensitive, the NVM functionality is usually expected to be provided at very little or no additional cost. In these systems, NVM is often used to store personalization data, trim coefficients, serial numbers and other manufacturing data. As a result, the required bitcounts are usually small. However, the presence of even these small amounts of NVM adds significantly to the capability and desirability of the IC in customer systems.

In order to satisfy such requirements for the presence of NVM in an IC, there exist several single-poly CMOS NVM structures. As CMOS feature sizes shrink to deep sub-micron levels, some of these structures fail to operate as expected, often for reasons related to the lower junction breakdown voltages in scaled processes.

In addition to the problems of decreasing transistor and junction breakdown voltages, deep sub-micron CMOS logic, RF and Analog processes introduce other factors that must be considered in the design and operation of single-poly NVM cells. These include scaled gate oxides and MIM capacitors. Scaled gate oxides help to ameliorate the issue of decreasing transistor and junction breakdowns by requiring lower voltages for Fowler-Nordheim (FN) tunneling.

However, thin gate oxides also force the process designer and manufacturing fab to ensure that the transistor gate oxide quality is extremely high in order to maintain any data retention capability as the oxide thickness is decreased. Therefore, as gate dielectrics are scaled, it becomes increasingly difficult to satisfy the reliability specifications of numerous NVM applications.

Accordingly, it would be desirable to provide an improved CMOS NVM bitcell structure for overcoming the problems in the art.

### BRIEF DESCRIPTION OF THE DRAWINGS

The embodiments of the present disclosure are illustrated by way of example and not limited by the accompanying figures, in which like references indicate similar elements, and in which:

FIG. 1 is a cross-sectional view of a bitcell structure according to one embodiment of the present disclosure;

FIG. 2 is a schematic view of a method of programming the bitcell structure of FIG. 1 according to one embodiment of the present disclosure;

FIG. 3 is a schematic view of a method of erasing the bitcell structure of FIG. 1 according to one embodiment of the present disclosure;

FIG. 4 is a schematic view of a read circuit for reading the bitcell structure of FIG. 1 according to one embodiment of the present disclosure;

FIG. 5 is a schematic view of an array of bitcell structures according to one embodiment of the present disclosure;

FIG. 6 is a cross-sectional view of the array of FIG. 5, taken along line 5-5;

FIG. 7 is a cross-sectional view of a bitcell structure according to another embodiment of the present disclosure;

FIG. 8 is a schematic view of a method of programming the bitcell structure of FIG. 7 according to an embodiment of the present disclosure;

FIG. 9 is a schematic view of a method of erasing the bitcell structure of FIG. 7 according to an embodiment of the present disclosure;

FIG. 10 is a schematic view of a method of reading the bitcell structure of FIG. 7 according to an embodiment of the present disclosure; and

FIG. 11 is a cross-sectional view of a bitcell structure according to yet another embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

According to one embodiment of the present disclosure, a bitcell structure makes use of a MIM capacitor structure available via deep sub-micron CMOS processes. The bitcell structure incorporating the MIM capacitor structure solves problems in the art posed by decreased junction/oxide breakdowns and oxide thicknesses in such scaled processes. In one embodiment, the bitcells eliminate any transistors, commonly CMOS, from the storage node in order that their gate oxide does not affect data retention of the device. In addition, the bitcell embodiments of the present disclosure do not add to the wafer process cost because they require no additional processing steps. Furthermore, in one embodiment, the bitcell structure allows for achieving a denser single-poly NVM array than that achievable with conventional single-poly NVM bitcells.

According to one embodiment of the present disclosure, the NVM bitcell structure eliminates a transistor gate and its thin gate oxide from the storage node of the device. Instead, the stored charge resides on a separate capacitor, for example, a MIM capacitor. Accordingly, the bitcell structure can be used independently of technology node. In addition, although a MIM capacitor has been disclosed, the bitcell structure storage node is not limited to only MIM capacitors. Furthermore, with the embodiments of the present disclosure, in the presence of a good enough capacitor, it is unnecessary to have a gate oxide robust enough for Non-Volatile Memory applications. This allows use of the bitcell structure on other technology platforms such as compound semiconductors.

The embodiments of the present disclosure overcome problems in the art, in part, because the transistor gate oxide is no longer in the storage node. Accordingly, the data retention problems caused by CMOS scaling of the gate oxide are eliminated.

FIG. 1 is a cross-sectional view of a bitcell structure 10 according to one embodiment of the present disclosure. Bitcell structure 10 includes a substrate 12 and a first MIM capacitor 14 (C1). Substrate 12 can include any material suitable for the requirements of a particular Non-Volatile Memory application, including semiconductor or non-semiconductor materials. MIM capacitor 14 includes a bottom plate 16, a MIM capacitor dielectric 18, and a top plate 20. Bitcell structure further includes a second MIM capacitor 22 (C2). MIM capacitor 22 includes a bottom plate 16, a MIM capacitor dielectric 24, and a top plate 26. The capacitance of the first MIM capacitor 14 (C1) is larger than the capacitance of the second MIM capacitor (C2). As illustrated, MIM capacitor 14 and MIM capacitor 22 share a common bottom plate 16. In another embodiment, the bottom plate of the first MIM capacitor 14 is separate from but electrically coupled to the bottom plate of the second MIM capacitor 22. In addition to implementations with common or electrically connected bottom plates, this pair of capacitors can also be instead constructed with common or electrically connected top plates or with the top plate of one capacitor connected to the bottom plate of the other. In addition, in a process where multiple types of MIM capacitors can be formed, the two capacitors need not be of identical type.

Bitcell structure 10 further includes a first conductive line 28 (ML1) and a second conductive line 30 (ML2). Vias 32 electrically couple first conductive line 28 to the top plate 20 of MIM capacitor 14. Similarly, vias 34 electrically couple second conductive line 30 to the top plate 26 of MIM capacitor 22. Bitcell structure 10 still further includes a dielectric, generally indicated by reference numeral 36.

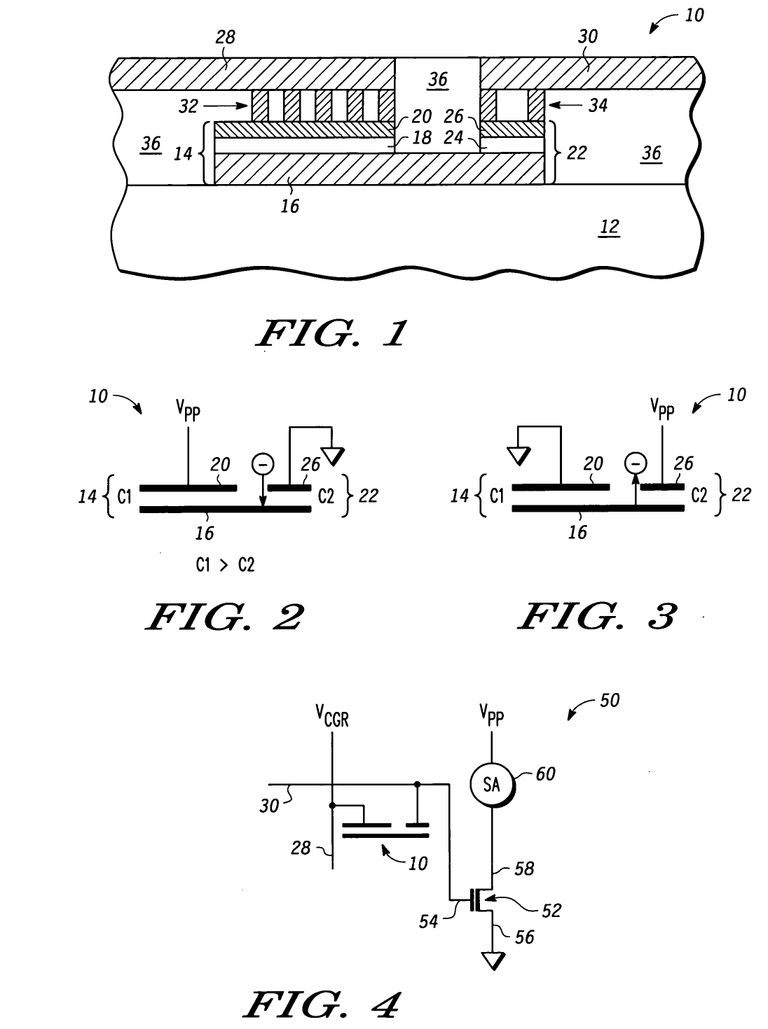

FIG. 2 is a schematic view of a method of programming the bitcell structure 10 of FIG. 1 via a program operation according to one embodiment of the present disclosure. To program the bitcell structure 10, a voltage Vpp is applied to the top plate 20 of the first MIM capacitor 14 (C1) while the top plate 26 of the second MIM capacitor 22 (C2) is grounded. Accordingly, electron flow occurs from the top plate 26 of the second MIM capacitor 22 (C2) to the bottom plate 16, as shown in FIG. 2.

In other words, programming of bitcell structure 10 can be accomplished by raising ML1 to a high potential while grounding ML2. Since C2<C1, the field is largely confined to C2 and allows electrons to move unto the bottom plate 16 of the dual MIM capacitor (14, 22) through the dielectric 24 in C2. Removing the bias from ML1 decreases the fields across both C1 and C2 and leaves the electrons trapped on the bottom plate of the dual MIM capacitor. The same operation could also be accomplished by grounding ML1 and placing a large negative bias on ML2. Generally, the programming biases can be split between ML1 and ML2, as long as the potential of ML1 is higher than that of ML2 and the potential difference between ML1 and ML2 is large enough to create sufficient field across C2.

FIG. 3 is a schematic view of a method of erasing the bitcell structure 10 of FIG. 1 via an erase operation according to one embodiment of the present disclosure. To erase the bitcell structure 10, a voltage Vpp is applied to the top plate 26 of the second MIM capacitor 22 (C2) while the top plate 20 of the first MIM capacitor 14 (C1) is grounded. Accordingly, electron flow occurs from the bottom plate 16 to the top plate 26 of the second MIM capacitor 22 (C2), as shown in FIG. 3.

In other words, the bitcell structure 10 can be erased by grounding ML1 and raising ML2 to a high positive bias. The field across C2 now points in the opposite direction, allowing the electrons trapped on the bottom plate 16 of the dual MIM capacitor (14, 22) to move through the dielectric 24 in C2, erasing the bitcell. In general, the erase operation can be accomplished with any combination of biases on ML1 and ML2, such that the potential of ML2 is higher than that of ML1 and the difference is large enough to create a sufficiently large field across C2.

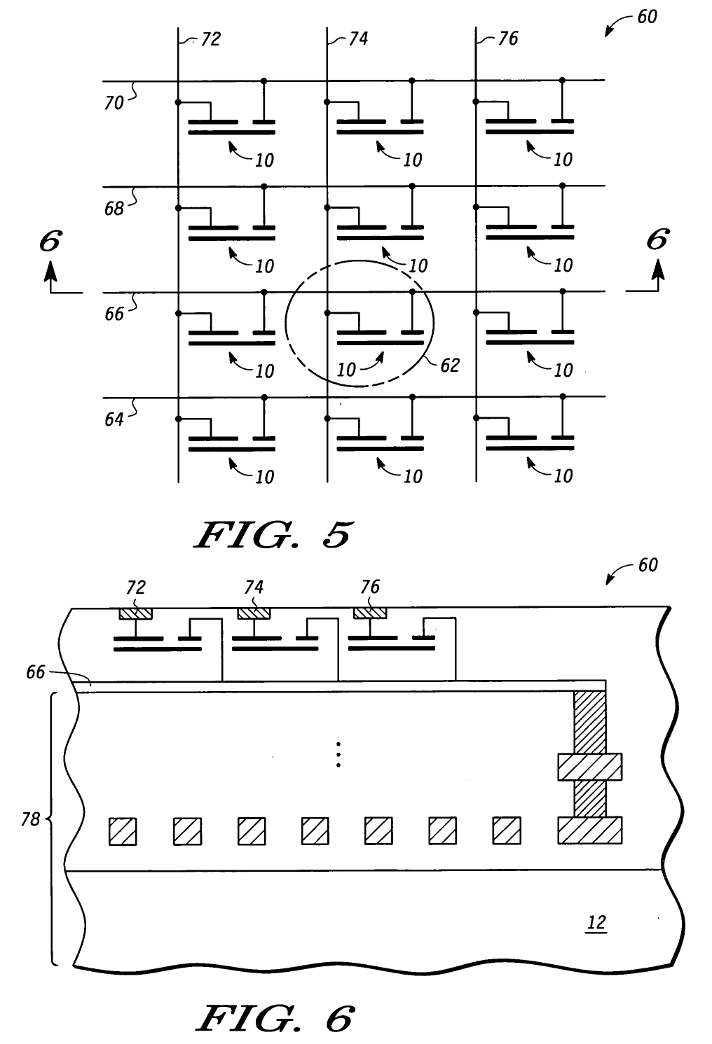

FIG. 4 is a schematic view of an example read circuit 50 for reading the bitcell structure 10 of FIG. 1 according to one embodiment of the present disclosure. Read circuit 50 includes a read transistor 52 that comprises a gate 54, source 56, and drain 58. Read circuit 50 further includes a sense-amplifier 60 electrically coupled between a voltage source Vdd and the drain 58 of read transistor 52. Sense-amplifier 60 senses either the presence of drain current flow or the absence of drain current flow at read transistor 52. Gate 54 of the read transistor 52 electrically couples to the second MIM capacitor 22 (C2) of bitcell structure 10 through a metal line 30 (ML2). During a read operation, the first MIM capacitor 14 (C1) of bitcell structure 10 couples to a voltage VcgR, also referred to as a wordline READ voltage, through metal line 28 (ML1). Accordingly, if the bottom plate 16 of the bitcell structure 10 has enough charge (i.e., an amount of charge above a threshold amount), then there is no drain current at the read transistor 52. Alternatively, if the bottom plate 16 of the bitcell structure 10 has a charge level below a threshold amount, then there is drain current at the read transistor 52. FIG. 4 is representative of one example of a schematic representation for performing a read operation of the bitcell structure 10. Other configurations for performing a read operation by sensing the quantity of charge stored on bottom plate 16 are also possible.

In other words, one method of reading the bitcell 10 involves temporarily connecting it to a MOS transistor (or MOSFET). During a Read operation, either ML1 or ML2 is connected to the gate of the MOSFET. For this example, assume ML2 is connected to the gate of a “READ” MOSFET. The MOSFET source and drain are biased with the same consideration for speed of operation limitations as for a conventional bitcell. The other metal line ML1 is then biased to a potential VcgR, such that VtE<VcgR<VtP, where VtE and VtP are the apparent program and erase thresholds of the MOSFET as seen from ML1. Again, erased bitcells will conduct current and programmed bitcells will not, allowing the states to be distinguished.

FIG. 5 is a schematic view of an array 60 of bitcell structures 10 according to one embodiment of the present disclosure. In particular, array 60 includes substantially orthogonal rows and columns of bitcells 10. For illustration purposes, array 60 comprises rows 64, 66, 68, 70 and columns 72, 74 and 76. The specific number of rows and columns is determined according to the requirements of a given storage application. In one embodiment, bitcells 10 of array 60 can be programmed or erased with the use of a split-bias scheme. Use of the split-bias scheme advantageously eliminates the necessity for select gate transistors to choose the bitcell to be operated upon during a program, erase, or read operation. Bitcells that reside in the same column share a common Column Line (ML1) while bitcells that reside in a row share a common Row Line (ML2). A goal of split-bias operation is to select and use biases on desired ones of the Row and Column lines such that a single bitcell at an intersection of a particular Row Line and a particular Column Line is operated upon, for example, as illustrated by reference numeral 62. For the following discussion, it is noted that C1 (the capacitor connected to the Column Line in each bitcell) is greater than C2 (the capacitor connected to the Row Line in each bitcell). In other words, C1>C2.

In a first programming scheme, the programming operation is performed as follows and includes the use of a split-bias scheme. To program the selected bitcell 62 using the split-bias scheme, program biases Vpp2 and Vpp1 are applied to row line 66 and column line 74, respectively. All other row lines (64, 68, 70) and column lines (72, 76) are grounded. The total voltage across the capacitors (i.e., C1 and C2) of the selected bitcell 62 is now Vpp1-Vpp2 (i.e., the voltage difference between Vpp1 and Vpp2). Bitcells sharing the same column line 74 have a potential Vpp1 across their capacitors while those bitcells on row line 66 are subjected to a potential drop of Vpp2. If the magnitude of (Vpp1-Vpp2) is greater than the magnitudes of Vpp1 and Vpp2 separately, then bitcell 62 can be programmed without programming other bitcells sharing the same row line or column line. This can be done, for example, by making Vpp1 positive and Vpp2 negative. Bitcells which do not share either a row line or column line with bitcell 62 do not experience any potential drop and, therefore, will not be programmed or erased. Accordingly, per this first programming scheme, selected bitcell 62 is the only bitcell programmed.

In a second programming scheme, the programming operation is performed as follows to avoid the generation of a negative bias. The programming operation includes an alternative split-bias scheme for programming bitcell 62 in array 60. The alternative split-bias scheme is to ground all column lines, except column line 74 and apply a positive inhibitory bias, Vinhp, to all row lines except row line 66. Row line 66 is then grounded to program bitcell 62. The potential across bitcell 62 is now Vpp1. Bitcells on the same row line as selected bitcell 62 have no voltage drop across them and, therefore, are not programmed. Bitcells on the same column line as selected bitcell 62 experience a potential drop of (Vpp1-Vinhp). Since Vinhp is positive, the quantity (Vpp1-Vinhp) is of smaller magnitude. Accordingly, the bitcells on the same column line as selected bitcell 62 that experience the potential drop of (Vpp1-Vinhp) are not programmed. The magnitude of the potential across all other bitcells is Vinhp, which can be chosen to be small enough so as not to program the corresponding bitcells. Accordingly, per this second programming scheme, selected bitcell 62 is the only bitcell programmed.

In a third programming scheme, the programming operation is performed as follows. In this third programming scheme, the roles of the rows and columns are interchanged from that of the second programming scheme. That is, in the third programming scheme, the inhibitory biases are applied to the unselected columns and the unselected rows are grounded. The inhibitory biases are negative biases in this third programming scheme. Accordingly, column line 74 is grounded while row line 66 is biased with a negative polarity Vpp2. Accordingly, per this third programming scheme, selected bitcell 62 is the only bitcell programmed.

In addition to the program schemes, the embodiments of the present disclosure include erase schemes. That is, the erase schemes can include split-bias schemes for erasing selected bitcell 62 of array 60 and are very similar to those schemes used for programming the same. For example, the programming methods described above can be used to erase the selected bitcell by changing the polarity of the applied biases. However, merely changing the polarity of the applied biases would lead to the use of predominantly negative voltages for erasing the selected bitcell. Since negative voltages are usually more difficult to generate on-chip, alternative methods of erasure using primarily positive voltages are desired, as discussed further herein below.

In a first erase scheme, the erase operation is substantially similar of the first programming scheme, however the roles of Vpp1 and Vpp2 are reversed. So, for example, instead of a positive Vpp1 and a negative Vpp2, the equivalent erase scheme would use a negative Vpp1 on column line 74 and a positive Vpp2 on row line 66 with all other row and column lines grounded. Similar to the situation in the first programming scheme, bitcells which share neither a row line nor a column line with the selected cell 62 of the array 60 do not see any applied bias and are not erased. Bitcells sharing a column line experience a bias of Vpp1 while bitcells sharing a row line experience a bias of Vpp2. With negative Vpp1 and positive Vpp2, the respective biases are smaller in magnitude than (Vpp2-Vpp1). With appropriately selected values for Vpp1 and Vpp2, the biases are too small to erase the other bitcells, while (Vpp2-Vpp1) is large enough to erase selected bitcell 62. Accordingly, per this first erase scheme, selected bitcell 62 is the only bitcell erased.

In a second erase scheme, the erase operation is substantially similar to the second programming scheme. However, the second erase scheme is intended to avoid the necessity for generating negative voltages for erasing the bitcell. In this second erase scheme, Vpp2 is applied to row line 66 while all other row lines are grounded. An inhibitory bias, Vinhe, is applied to all column lines except column line 74. Column line 74 is grounded to erase the selected bitcell 62. Bitcells on the same column as the selected cell have no applied bias and so are not erased. Bitcells on other columns, not common with the column line of the selected bitcell have Vinhe applied across them. Vinhe is selected to be low enough not to be capable of causing erasure by itself and so these bitcells are not erased. Other bitcells on row line 66 have the differential voltage of (Vpp2-Vinhe) applied across them and so are not erased. The full Vpp2 bias is applied across the selected bitcell 62. Accordingly, per this second erase scheme, selected bitcell 62 is the only bitcell erased.

In a third erase scheme, the erase operation interchanges the roles of the row lines and column lines in the second erase scheme. That is, in the third erase scheme, the inhibitory biases are applied to all row lines except row line 66, which is grounded. All column lines except column line 74 are also grounded, while Vpp1 is applied to column line 74. Vpp1 is of a negative polarity in order to erase the selected bitcell, wherein the selected bitcell is the only cell erased with properly chosen values of Vpp1 and Vinhe.

Accordingly, in the dual MIM capacitor version of the bitcell structure 10, the presence of two control gate capacitors and their associated metal lines enables a “half-select” bitcell selection mechanism. Because of this, the ability to create an array of bitcells with no “select gate transistor” to protect unselected bitcells is possible. Such an array is denser, and therefore more cost-effective, than an array which requires a select transistor.

FIG. 6 is a cross-sectional view of the array 60 of FIG. 5, taken along line 6-6. Underlying the array 60 is a substrate 12 and addition circuitry. The additional circuitry may include, for example, high voltage components (row and column decoders, charge pumps, high voltage switches, etc.) and sense amplifiers, as indicated generally by reference numeral 78. As illustrated in FIG. 6, the bitcell embodiments of FIGS. 1 and 5 provide an advantage that the silicon area beneath the bitcells is available so that additional components of the integrated circuit can be fabricated without any substantial increase in the die area. The substrate and additional circuitry is determined according to the requirements of a particular integrated circuit design. As a result, a high-efficiency array layout is possible.

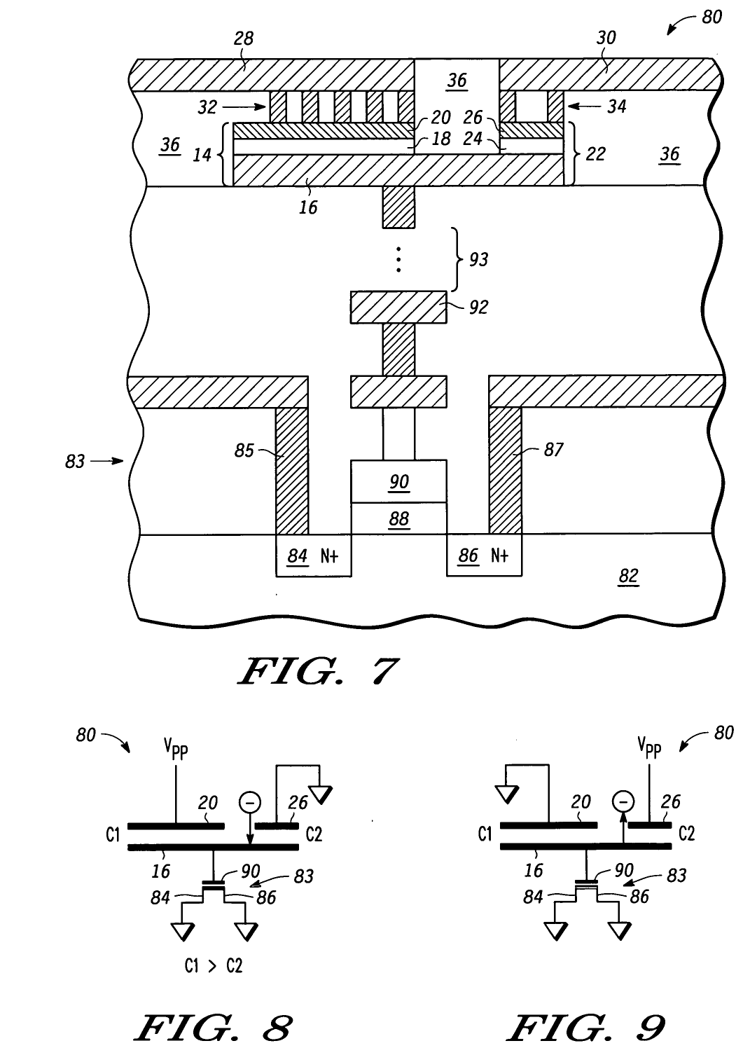

FIG. 7 is a cross-sectional view of a bitcell structure 80 according to another embodiment of the present disclosure. Bitcell structure 80 includes a substrate 82 and a first MIM capacitor 14. MIM capacitor 14 includes a bottom plate 16, a MIM capacitor dielectric 18, and a top plate 20. Bitcell structure further includes a second MIM capacitor 22. MIM capacitor 22 includes a bottom plate 16, a MIM capacitor dielectric 24, and a top plate 26. As illustrated, MIM capacitor 14 and MIM capacitor 22 share a common bottom plate 16. In another embodiment, the bottom plate of the first MIM capacitor 14 is separate from but electrically coupled to the bottom plate of the second MIM capacitor 22. In another embodiment, the top plates of the capacitors could be coupled and used as the storage component instead of the bottom plates. In yet another embodiment, the top plate of one capacitor and the bottom plate of the other could be coupled and used as the storage component. Bitcell structure 80 further includes a first metal line 28 and a second metal line 30. Vias 32 electrically couple first metal line 28 to the top plate 20 of MIM capacitor 14. Similarly, vias 34 electrically couple second metal line 30 to the top plate 26 of MIM capacitor 22. Bitcell structure 80 still further includes an interlevel dielectric, generally indicated by reference numeral 36.

Bitcell structure 80 still further includes a MOS transistor 83. MOS transistor 83 includes a source region 84 and drain region 86 formed within an active region of substrate 82. MOS transistor 83 further includes gate dielectric 88 and a floating gate 90. Floating gate 90 comprises a conductive gate electrode, for example, metal, polysilicon, or other suitable gate electrode material and/or structure. Electrical contact to the source region 84 and drain region 86 is accomplished via metalizations 85 and 87, respectively.

Further with respect to the embodiment of FIG. 7, the bottom plate 16 of MIM capacitor 14 and MIM capacitor 22 electrically couples to the floating gate 90 of transistor 83. In general, the storage element of the MIM capacitor arrangement is electrically coupled to the floating gate 90 of transistor 83. In one embodiment, the bottom plate 16 electrically couples to the floating gate 90 using, for example, metal layers and conductive vias 92, as further represented generally by reference numeral 93.

FIG. 8 is a schematic view of a method of programming the bitcell structure 80 of FIG. 7 via a program operation according to an embodiment of the present disclosure. As discussed herein, bitcell structure 80 includes transistor 83 that comprises a source 84, drain 86, and gate electrode 90. The bottom plate 16 of the bitcell structure is electrically coupled to the gate electrode 90 of transistor 83. To program the bitcell structure 80, a voltage Vpp is applied to the top plate 20 of the first MIM capacitor 14 (C1) while the top plate 26 of the second MIM capacitor 22, as well as the source 84 and drain 86 of transistor 83, are grounded. Recall that the capacitance of capacitor 14 is greater than the capacitance of capacitor 22 (i.e., C1>(C2+C_{Gate}) where C_{Gate} is the capacitance of the MOSFET Gate). Accordingly, electron flow occurs from the top plate 26 of the second MIM capacitor 22 (C2) to the bottom plate 16, as shown in FIG. 8.

FIG. 9 is a schematic view of a method of erasing the bitcell structure of FIG. 7 according to an embodiment of the present disclosure. To erase the bitcell structure 80, a voltage Vpp is applied to the top plate 26 of the second MIM capacitor 22 (C2). The top plate 20 of the first MIM capacitor 14 (C1), as well as the source 84 and drain 86 of the transistor 83, are grounded. Accordingly, electron flow occurs from the bottom plate 16 to the top plate 26 of the second MIM capacitor 22 (C2), as shown in FIG. 9.

Accordingly, the dual MIM capacitor control gate structure of FIG. 7 eliminates the necessity of applying an erase bias to the substrate altogether. As discussed, in one embodiment, the bitcell structure of FIG. 7 includes two top plates sharing the same bottom plate of the MIM capacitor structure. In such a structure, the bitcell can be erased by biasing the second metal line 30 (ML2) without applying any high biases to the storage transistor source 84 or drain 86 electrode. Since the second parallel capacitor 22 (C2) has a much smaller magnitude than the first capacitor 14 (C1), the bitcell 10 can be erased by applying a high bias to the second metal line 30 (ML2) while grounding all other electrodes of the bitcell. This creates a field across the second MIM capacitor 22 (C2) so that electrons tunnel off of the storage stack through C2, erasing the bitcell.

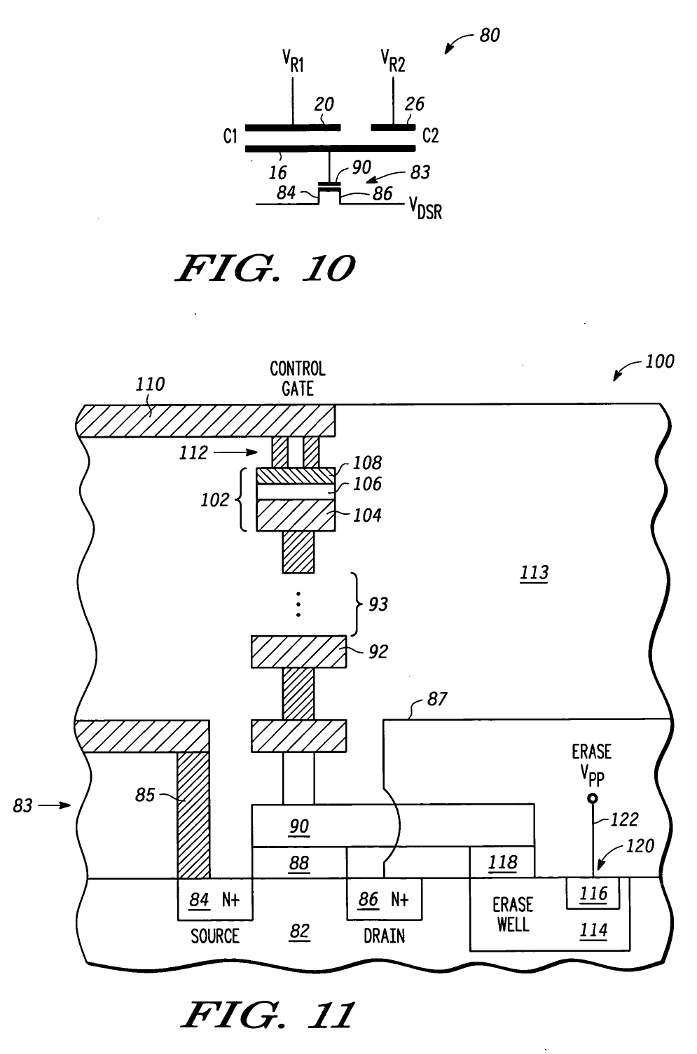

FIG. 10 is a schematic view of a read circuit for reading the bitcell structure of FIG. 7 according to an embodiment of the present disclosure. As discussed herein, the bottom plate 16 of the bitcell structure 80 is electrically coupled to gate 90 of transistor 83. To read the bitcell structure 80, the bottom plate 16 is allowed to float (i.e., left floating). Appropriate first and second read voltages, Vr1 and Vr2, respectively, are applied to the top plates (20 and 26) of the first and second MIM capacitors 14 (C1) and 22 (C2), respectively. A source/drain read voltage (VdsR) is applied between the drain 86 and source 84 of transistor 83 with the source 84 of transistor 83 optionally grounded. If the charge on the bottom plate 16 of the bitcell structure 10 is large enough, there is no drain current in the transistor 83. Accordingly, if the bottom plate 16 of the bitcell structure 80 has enough charge (i.e., an amount of charge above a threshold amount), then there is no drain current in the read transistor 83. Alternatively, if the bottom plate 16 of the bitcell structure 80 has a charge level below a threshold amount, then there is drain current in the read transistor 83.

In other words, with respect to the bitcell structure 80 of FIG. 7, the read operation can be conventional. The metal lines 28 (ML1) and 30 (ML2) are biased at VcgR, where VtE<VcgR<VtP. VtE is the threshold voltage of an erased bitcell and VtP is the threshold voltage of a programmed bitcell. A non-zero drain-source voltage is chosen to provide enough channel current to meet the required speed requirements whilst not creating any hot carriers which could disturb an erased bitcell being read or other cells which share the same bitline. In a programmed cell, the applied gate bias is too low to turn the MOSFET on and no channel current flows. This allows programmed and erased bitcells to be distinguished from each other.

Further with respect to the bitcell structure 80 of FIG. 7, the biases on metal lines 28 (ML1) and 30 (ML2) can be different. The fact that there are two separate capacitors connected to ML1 and ML2 with separate capacitive coupling to the floating gate can be used to make a “half-select scheme” in an orthogonal array. The idea is that only the bitcell at the intersection of an appropriately biased metal line 28 (ML1) and an appropriately biased metal line 30 (ML2) is affected by the planned operation. Accordingly, the need for a “select gate transistor” to protect unselected bitcells is eliminated.

As discussed herein, the structure of FIG. 7 stores charge on the bottom plate of the MIM capacitors (14, 22), the metal stack (92, 93) and the gate (90) of the MOS transistor 83. As processes are scaled into the deep sub-micron region, the MOS gate oxide 88 thickness must be decreased. Even with novel dielectrics substituted for oxide, the electrical thickness of the dielectric has to be decreased. For the NVM bitcell, this represents a potential reliability issue. Defects in the gate oxide can create leakage paths through the dielectric and allow charge to enter or leave the storage stack. Such a charge entering or leaving the storage stack alters the stored data value. For thinner oxide, the probability that a single defect will cause a charge leakage path increases. Charge leakage also takes place via thermionic emission, Fowler-Nordheim tunneling, direct tunneling and other dielectric conduction mechanisms. Most leakage components, including the three named above, increase in magnitude as the gate dielectric is scaled.

The bitcell structure 10, illustrated in FIG. 1, offers a means of avoiding the reliability and data retention problem posed by scaled gate dielectrics. Bitcell 10 eliminates the MOS transistor and its gate from the storage node. Because the transistor is not in the storage node, the transistor is not involved in the program and erase operations and no high biases are applied to any of the transistor electrodes. Without the transistor in the storage node, there is no opportunity for the stored charge to tunnel or leak through its gate dielectric. Accordingly, the bitcell design of FIG. 1 avoids both the problems of decreased breakdown and data retention.

FIG. 11 is a cross-sectional view of a bitcell structure 100 according to yet another embodiment of the present disclosure. Bitcell structure 100 includes a substrate 82 and a single MIM capacitor 102. MIM capacitor 102 includes a bottom plate 104, a MIM capacitor dielectric 106, and a top plate 108. Bitcell structure 100 further includes a metal line 110. Vias 112 electrically couple metal line 110 to the top plate 108 of MIM capacitor 102. Bitcell structure 100 still further includes an interlevel dielectric, generally indicated by reference numeral 113.

Bitcell structure 100 still further includes a MOS transistor 83. MOS transistor 83 includes a source region 84 and drain region 86 formed within an active region of substrate 82. MOS transistor 83 further includes gate dielectric 88 and a floating gate 90. Floating gate 90 comprises a conductive gate electrode, for example, metal, polysilicon, or other suitable gate electrode material and/or structure. Electrical contact to the source region 84 and drain region 86 is accomplished via metalizations 85 and 87, respectively.

Further with respect to the embodiment of FIG. 11, the bottom plate 104 of MIM capacitor 102 electrically couples to the floating gate 90 of transistor 83. In one embodiment, the bottom plate 104 electrically couples to the floating gate 90 using, for example, metal layers and conductive vias 92, as further represented generally by reference numeral 93.

Bitcell structure 100 still further includes erase well 114 formed within substrate 82. A contact region 116 is formed in erase well 114 for providing for electrical contact to the well. A dielectric 118 is formed over a portion of erase well 114. Furthermore, a electrode is formed over the dielectric 118. As illustrated, the electrode formed over the dielectric 118 is an extension of gate electrode 90 of transistor 83. Alternatively, electrode formed over the dielectric 118 could be an electrode separate from gate electrode 90, but electrically coupled to the electrode formed over the dielectric 118. The combination of the electrode over the dielectric 118, the dielectric 118, and the erase well 114 form a capacitor structure 120.

As feature sizes decrease, the source and drain junctions become less able to sustain the voltages necessary for tunneling and the structure of FIG. 11 can be used to apply an erase bias to an N-Well diffusion instead of an N+source/drain junction. An advantage of the structure of FIG. 11 is that i) it can be used to shift the program and erase biases from the transistor source/drain junctions, and in that ii) the structure is smaller in area. For example, in conventional CMOS single-poly NVM bitcells, the value of the capacitance over the well diffusion must be significantly larger than the gate capacitance and this usually mandates a larger capacitor than required for the structure in FIG. 11. The cell structure in FIG. 11 allows program and erase operations to use all positive biases with the use of only one MIM capacitor. The penalty, though, is increased bitcell area. In addition, the increased program coupling minimizes the magnitude of the bias which needs to be applied for program operations. In the bitcell shown in FIG. 11, as in the multiple capacitor bitcells, the availability of multiple capacitively coupled terminals allows program, erase and read inhibit operations to be done through the use of different, appropriately-chosen, simultaneously-applied biases on the capacitor terminals.

As disclosed herein, the embodiments have been included MIM capacitors as the storage node. However, for the embodiment including two capacitors but no transistor in the storage node, it is possible to use double-poly capacitors or metal-insulator-poly capacitors. The double-poly capacitors or metal-insulator-poly capacitors provide the benefit of removing the thin transistor gate oxide from the storage node. Furthermore, a double-poly capacitor can generally be built more reliably than a MIM capacitor with current process technology.

In the foregoing specification, the disclosure has been described with reference to various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A non-volatile memory bitcell structure comprising:
a first metal-insulator-metal (MIM) capacitor having a first capacitance value, the first MIM capacitor including a first top plate, a first bottom plate, and a first dielectric disposed in-between the first top plate and the first bottom plate; and
a second metal-insulator-metal (MIM) capacitor having a second capacitance value, the second MIM capacitor including a second top plate, a second bottom plate, and a second dielectric disposed in-between the second top plate and the second bottom plate, wherein an element of the first MIM capacitor is electrically coupled in common with an element of the second MIM capacitor and wherein the first capacitance value is greater than the second capacitance value.

2. The NVM bitcell structure of claim 1, wherein the first dielectric is further disposed in-between the first top plate and a first portion of the first bottom plate, and wherein the second bottom plate is in common with and comprises a second portion of the first bottom plate, the second portion being a portion separate from the first portion of the first bottom plate.

3. The NVM bitcell structure of claim 2, wherein the bit cell structure can be programmed by applying a first voltage to the first top plate of the first MIM capacitor while applying a second voltage to the second top plate of the second MIM capacitor, the first voltage being larger than the second voltage by an amount sufficient to create a field across the second MIM capacitor, whereby electron flow occurs from the second top plate of the second MIM capacitor to the first bottom plate, and subsequent to removing at least one of the first and second voltages, electrons are trapped on the first bottom plate.

4. The NVM bitcell structure of claim 1, wherein the first dielectric is further disposed in-between a first portion of the first top plate and the first bottom plate, and wherein the second top plate is in common with and comprises a second portion of the first top plate, the second portion being a portion separate from the first portion of the first top plate.

5. The NVM bitcell structure of claim 1, wherein the first and second dielectrics comprise a same MIM capacitor dielectric material.

6. The NVM bitcell structure of claim 1, wherein the first dielectric comprise a first MIM capacitor dielectric material and the second dielectric comprises a second MIM capacitor material, the first MIM capacitor dielectric material being different from the second MIM capacitor dielectric material.

7. The NVM bitcell structure of claim 1, further comprising:
a substrate, wherein the first MIM capacitor and the second MIM capacitor are formed overlying the substrate;
a first conductive line electrically coupled to the top plate of the first MIM capacitor using one or more first conductive via; and
a second conductive line electrically coupled to the top plate of the second MIM capacitor using one or more second conductive via.

8. The NVM bitcell structure of claim 7, further comprising:
a dielectric, wherein the first and second MIM capacitors are disposed with the dielectric, and wherein the one or more first and second conductive via extend from a respective one of the first and second conductive lines within the dielectric to a corresponding first and second top plate.

9. The NVM bitcell structure of claim 1, wherein the bit cell structure can be programmed by applying a first bias voltage to the first top plate of the first MIM capacitor while applying a second bias voltage to the second top plate of the second MIM capacitor, the first bias voltage being larger than the second bias voltage by an amount sufficient to create a field across the second MIM capacitor, whereby electron flow occurs from the second top plate of the second MIM capacitor to the second bottom plate, and subsequent to removing at least one of the first and second bias voltages, electrons are trapped on the second bottom plate.

10. The NVM bitcell structure of claim 1, wherein the bit cell structure can be erased by applying a first bias voltage to the second top plate of the second MIM capacitor while applying a second bias voltage to the first top plate of the first MIM capacitor, the first bias voltage being larger than the second bias voltage by an amount sufficient to create a field across the second MIM capacitor, whereby electrons previously trapped on the second bottom plate flow from the second bottom plate of the second MIM capacitor to the second top plate.

11. The NVM bitcell structure of claim 1, further comprising:
a read transistor having gate, source, and drain terminals, the gate terminal being electrically coupled to either the first or the second MIM capacitor and one of either the source or drain terminal being electrically coupled to a first potential, and a sense amplifier electrically coupled between a second potential and the other of the source and drain terminal of the read transistor, wherein the sense amplifier senses either the presence or the absence of channel current flow at the read transistor.

12. The NVM bitcell structure of claim 1, further comprising:
a two-dimensional array of bitcell structures, wherein the two-dimensional array comprises substantially orthogonal rows and columns of bitcell structures, further wherein the bitcell structures can be programmed or erased with the use of a split-bias scheme.

13. The NVM bitcell structure of claim 12, further comprising:
column lines and row lines, wherein bitcell structures that reside in a similar column share a common column line and wherein bitcell structures that reside in a similar row share a common row line, further wherein programming or erasing the bitcell structures with the use of the split-bias scheme comprises selecting and using biases on desired ones of the row and column lines such that a single bitcell structure at an intersection of a particular row and column is operated on.

14. The NVM bitcell structure of claim 1, further comprising:
a substrate, wherein the first MIM capacitor and the second MIM capacitor are formed overlying the substrate; and
a MOS transistor having a source region and a drain region formed within an active region of the substrate, the MOS transistor further having a floating gate and a gate dielectric disposed between the floating gate and the active region, further wherein the electrically coupled elements of the first MIM capacitor and the second MIM capacitor are electrically coupled to the floating gate.

15. The NVM bitcell structure of claim 2, further comprising:
a substrate, wherein the first MIM capacitor and the second MIM capacitor are formed overlying the substrate; and
a MOS transistor having a source region and a drain region formed within an active region, wherein the active region comprises a portion of the substrate or an active region within a layer overlying the substrate, the MOS transistor further having a floating gate and a gate dielectric disposed between the floating gate and the active region, further wherein the first bottom plate is electrically coupled to the floating gate.

16. The NVM bitcell structure of claim 15, wherein the bit cell structure can be programmed by applying a first bias voltage to the first top plate of the first MIM capacitor while applying a second bias voltage to the second top plate of the second MIM capacitor and to the source and drain regions of the MOS transistor, the first bias voltage being larger than the second bias voltage by an amount sufficient to create a field across the second MIM capacitor, whereby electron flow occurs from the second top plate of the second MIM capacitor to the second bottom plate, and subsequent to removing at least one of the first and second bias voltages, electrons are trapped on the second bottom plate.

17. The NVM bitcell structure of claim 15, wherein the bit cell structure can be erased by applying a first bias voltage to the second top plate of the second MIM capacitor while applying a second bias voltage to the first top plate of the first MIM capacitor and to the source and drain regions of the MOS transistor, the first bias voltage being larger than the second bias voltage by an amount sufficient to create a field across the second MIM capacitor, whereby electrons previously trapped on the second bottom plate flow from the second bottom plate of the second MIM capacitor to the second top plate.

18. A non-volatile memory (NVM) bitcell structure comprising:
a first metal-insulator-metal (MIM) capacitor having a first capacitance value, the first MIM capacitor including a first top plate, a first bottom plate, and a first dielectric disposed in-between the first top plate and the first bottom plate;
a second capacitor having a second capacitance value, the second capacitor including an element electrically coupled in common with an element of the first MIM capacitor and wherein the first capacitance value is greater than the second capacitance value;
a substrate, wherein the first MIM capacitor is formed in an interlevel dielectric overlying the substrate;
a MOS transistor having a source region and a drain region formed within an active region of the substrate, the MOS transistor further having a floating gate and a gate dielectric disposed between the floating gate and the active region, further wherein the first bottom plate is electrically coupled to the floating gate; and
an erase structure, wherein the erase structure comprises an erase well formed within the substrate, a dielectric layer formed over a portion of the erase well, and an electrode formed overlying the dielectric layer, wherein the electrode is electrically coupled to the floating gate of the MOS transistor and wherein the electrode, dielectric, and erase well form the second capacitor of the NVM bitcell structure.

19. An integrated circuit, said the integrated circuit comprising a non-volatile memory bitcell structure as claimed in claim 1.

20. A method of making a non-volatile memory bitcell comprising:
forming a first metal-insulator-metal (MIM) capacitor having a first capacitance value, the first MIM capacitor including a first top plate, a first bottom plate, and a first dielectric disposed in-between the first top plate and the first bottom plate; and
forming a second metal-insulator-metal (MIM) capacitor having a second capacitance value, the second MIM capacitor including a second top plate, a second bottom plate, and a second dielectric disposed in-between the second top plate and the second bottom plate, wherein an element of the first MIM capacitor is electrically coupled in common with an element of the second MIM capacitor and wherein the first capacitance value is greater than the second capacitance value.
